(19) United States
(12) Patent Application Publication
(10) Pub. No.: US 2010/0101635 A1
(43) Pub. Date: Apr. 29, 2010

(54) PACKAGINGS FOR THIN-LAYER SLICE-FORM PRODUCTS

(75) Inventors: Maik Köster, Osterholz-Scharmbeck (DE); Jan Kuhnke, Ritterhude (DE); Helmut Laschütza, Ritterhude (DE)

Correspondence Address: WOOD, HERRON & EVANS, LLP, 2700 CAREW TOWER, 441 VINE STREET, CINCINNATI, OH, 45202, US

(73) Assignee: CHRISTIAN SENNING VERPACKUNGSMASCHINEN GMBH & CO., Bremen (DE)

(21) Appl. No.: 12/578,116

(22) Filed: Oct. 13, 2009

(30) Foreign Application Priority Data
Oct. 14, 2008 (DE) 20 2008 013 468.4

(51) Int. Cl. H01L 31/048; B32B 1/06; B32B 1/04

(52) U.S. Cl. 136/251; 428/76

(57) ABSTRACT

The invention concerns a packaging for slice-form, in particular thin brittle products. According to the invention the packaging is a film wraparound packaging.

### BACKGROUND

The present invention concerns packagings for slice-form, in particular thin and/or brittle products, in particular thin silicon slices such as wafers, solar cells or the like.

Such products in slice form are used in the semiconductor or photovoltaic industry or in micromechanics. They can comprise for example silicon carbide or gallium arsenide, they can be of a circular or square shape, and they can be of a thickness of about 1 mm or markedly less. For example solar modules or integrated circuits (chips) can be produced from wafers. The products have to be packaged for transportation thereof between processes locations which are often far apart.

DE 20 2006 005 284 U1 discloses a solar cell container which is stable in respect of shape and which comprises a bottom and side walls shaped thereon. An insert in which a large number of solar cells or wafers are placed in mutually superposed stacked relationship can be introduced into the solar cell container. The inserts can be changed depending on the respective size or shape of the solar cell. The container is made from polypropylene, styropor or other plastic materials.

The production of those known containers together with inserts is relatively complicated and expensive as molds of a complicated configuration are required. In addition the containers and inserts are bulky and are of a quite large structural height. Removal of the individual solar cells from the packaging is difficult. The wafers which frequently have a very smooth, ground surface cling to each other and can only be separated from each other with difficulty. In addition the wafers are easily damaged in particular upon being removed. The brittleness of the material means that brittle fractures easily occur. The risk of fracture will increase further in view of the trend for products to become progressively thinner.

DE 11 2006 000 773 discloses a packaging method and a packaging in which a multiplicity of solar wafers are inserted in mutually parallel relationship and at predetermined spacings into rigid, so-called buffer bodies. The solar wafers which are placed in layers directly one upon the other are covered in a first packaging step by means of shrink film and the unit afforded thereby is then inserted into a container.

Those methods are also complicated and expensive, separation of the wafers which are laid one upon the other is difficult for the above-described reasons, and the risk of breakage and also the volume of the packaging are great.

### BRIEF SUMMARY

The object of the present invention is to provide packagings for products in slice form, in particular thin brittle products such as wafers or solar cells, with which the products can be packaged in a simple, inexpensive and secure fashion. The invention further seeks to provide that the packagings are of such a configuration that the products can be removed as far as possible quickly and without suffering damage. The invention further seeks to provide that the packagings are environmentally friendly.

In accordance with a first aspect, the invention attains that object with a packaging as set forth in the opening part of this specification, which is a film wraparound packaging.

Such a film wraparound packaging for slice-form, flat and in particular thin and brittle products such as wafers or solar cells can be used in a simple, inexpensive and environmentally friendly fashion in order to wraparound and thus package the usually delicate products. The required energy demand is comparatively low and heat sources as in the case of shrink films are not required. If in accordance with a preferred embodiment the products are wafers or solar cells, they can be stacked one upon the other in accordance with the invention and the entire wafer stack is wrapped directly into the film.

A preferred embodiment of the packaging is distinguished in that a cushioned and/or hard cover plate is disposed on the stack at top and bottom and the stack thus provided is wrapped into film. Cushioned or hard cover plates afford additional protection for the delicate products and the film wraparound packaging securely holds the products together, with the cover plate which can be fitted at top and/or bottom.

A particularly preferred development is one in which one or more separating elements are placed between the wafers or solar cells of the stack and the wafer stack with separating element or elements is wrapped directly in film. The one or more separating elements provide that the wafers do not cling directly to each other and, upon removal, can be carefully separated from each other without damage.

A development involves a combination of shrink film and film wraparound packaging so that in addition further protection is afforded by the shrink film, including in relation to unwanted opening of the packaging.

Desirably, the film packaging has a defined possible way of opening the film by means of a tear-open strip or a perforation in the film. Removal can be further improved in that way. The film can be specifically torn open by pulling on the tear-open strip.

In accordance with a further aspect in a packaging of the kind set forth in the opening part of this specification, the invention attains the object in that at least one separating element is arranged between adjacent wafers.

As already mentioned hereinbefore, the provision of at least one separating element between adjacent wafers, but in particular between all adjacent wafers of a stack, can ensure that the wafers can be separated from each other quickly and without damage. Desirably, the separating element is in the form of a thin intermediate layer of a deformable material, in particular cardboard, paper, tissue paper, film, felt, non-woven fleece, plastic material, foam, biologically degradable foam or laminated material. It is further preferable for the separating element to be of substantially the same form as a stacked wafer so that stacked adjacent wafers are not in contact and/or for the separating element to be of such a size and/or shape that adjacent wafers are only partially not in direct contact with each other.

Separability can be further improved by the separating element being of such a size and/or being so arranged between adjacent wafers that it partially projects laterally from adjacent wafers so that the projecting part can be manually gripped.

In an alternative embodiment, a plurality of separating elements are of substantially identical or differing nature, in particular so that the separating elements of various materials are layered in order by way of the layering to build up a pressure against the packaging film in the overall pack. That affords a highly stable packaging.

In a further alternative embodiment, it is provided that individual separating elements are of such a configuration in respect of their surface structure that the product can be very easily released from the separating element, in particular by virtue of the fact that an air flow between the separating element and the product becomes easily possible, as for example by knobs, structured air passages, cut-out or through passages in/on the separating element. As the stacked products cannot “thus adhere to each other”, they are lifted off.

In accordance with a further aspect, the invention further attains the object with a packaging having the features of claim 17 whereby at least one cushion element is arranged at an outside of the stacked wafers. Such a cushion element protects the wafers from external forces during transport, for example from shocks. Here the outside denotes the circumferential surface of a stack of wafers.

In accordance with a development, it is proposed that in addition a respective cushion element is arranged at opposite sides of the stacked wafers. The expression opposite sides is used to denote a top side and/or underside of a stack of wafers.

Preferably, the cushion element is of substantially the same size as a wafer so that complete protection is afforded. Alternatively a cushion element or a plurality of cushion elements can be arranged at the peripheral edge of the stacked wafers.

In accordance with a preferred embodiment, particularly for the case of a square or rectangular product, it is proposed that there is provided a cushion element which extends substantially over the entire edge and which has a plurality of straight wall portions. The corners are thereby particularly protected and preserved. Preferably the cushion element has a plurality of and preferably four recesses which in the packaged condition are arranged substantially opposite the corners of the wafers.

In an alternative embodiment, it is provided that at its outside the cushion element is of a higher strength or has a reinforcing layer.

Preferred materials for the cushion element are foam, cardboard, plastic material, felt, biologically degradable foam or laminated material.

In the case of a shrinkable film and/or a film wraparound packaging, it is preferable if the shrinkable film at least partially encloses and holds together the stacked wafers and the cushion element or elements.

In an alternative embodiment, it is provided that the means for holding the stacked wafers are in the form of a shell comprising a substantially stiff material. Packaging and unpackaging is particularly easily possible if the shell is composed of two half-shells or a plurality of shell portions, in particular if the half-shells can be fitted laterally onto the stacked wafers. Alternatively, the half-shells can be fitted onto the stacked wafers from above and below.

Alternatively, it is proposed that the holding means is in the form of a shell comprising a bottom and side walls and the stacked wafers can be fitted into an opening in opposite relationship to the bottom and into the container. Cushion elements are arranged between the bottom and the side walls and the stacked wafers to provide particular protection for the wafers. In addition a cover in the form of a cushion element closes the shell. In addition a shrinkable film can at least partially enclose the shell.

In an alternative embodiment, the bottom and the cover are provided with a groove and tongue so that the containers are better stackable. Fixing elements shaped on the shell provide that the wafers are fixed.

The invention further attains the object with a packaging having the features of claim 37, in which there is provided a carrier element for carrying a wafer, which is so designed that it is stackable together with a plurality of carrier elements.

It is advantageous in that respect if each wafer is arranged in a protected condition on the carrier element and a plurality of wafers are stacked in space-saving fashion. The stacks of carrier elements with wafers are further packaged, for example in a cardboard box or in the ways described hereinafter.

Desirably, the carrier element is so dimensioned that a wafer can be placed completely on one side of the carrier element so that it is well protected.

The security of the packaging and handling are further improved if the carrier element has one or more means for positioning a wafer on the carrier element. It is particularly preferred if the carrier element has a recess or depression into which a wafer can be laid. The depression is preferably so shaped that it substantially corresponds to the contour of a wafer and the wafer is arranged completely or substantially within the depression. The depression can be parallelepipedic, square or cylindrical.

The corners of a product are particularly protected against fracture if an outwardly extending recess is provided in one or all corners of a depression of the carrier element, the recess preferably having a rounded edge.

In a development, it is provided that a plurality of depressions or positioning means are provided on the carrier element, preferably in such a way that a plurality of wafers can be laid in relationship with each other on the carrier element.

The further development of the carrier elements provides that individual carrier elements are of such a configuration in respect of their surface structure that the product can be very easily released from the separating element, in particular by virtue of air flows being easily possible between the separating element and the product, such as for example by means of knobs, structured air passages, cut-outs or through openings in/on the separating element. For example, a plurality of raised portions and/or depressions are provided on one side of the carrier element, on which side a wafer can be deposited.

To achieve a minimal volume in respect of the overall packaging the carrier element is so dimensioned that the thickness thereof is small in relation to the width and/or length. The carrier element can be adapted to receive a wafer or a plurality of mutually juxtaposed wafers.

A particularly preferred variant is one in which an information carrier is arranged on the carrier element to be able to provide wafer-specific items of information, for example concerning time and place of manufacture. The information carrier is preferably arranged in the region of the edge of the carrier element, preferably on a side surface in adjacent relationship with the edge of the carrier element. It can have a barcode, RFID, data chip, printed label or the like.

A development proposes that one or more recess openings and/or one or more projections are provided in the edge region of the carrier element in order to position same using simple means or to be able to more easily remove them manually or by machine. The recess openings or projections are preferably provided at opposite edges of the carrier element and are of a rectangular shape or rounded.

Further advantages are afforded if the carrier element is made from paper, plastic material, film, deep-drawing film, metal or organically decomposable, fixed-structure materials.

The packaging is further reinforced by at least one cushion element being arranged at an outside of stacked carrier elements and/or at an outside or both mutually opposite outsides of the stacked carrier elements. It is of approximately the same size as a carrier element and is arranged at the peripheral edge of the stacked carrier elements. The cushion element can be of greater strength or can have a reinforcing layer at its outside. Preferred materials are foam, cardboard, plastic material or laminated materials.

Preferably, there are provided means for holding the stacked carrier elements, which for example are in the form of film wraparound packaging and/or shrinkable film which at least partially enclose the stacked carrier elements and optionally the cushion element or elements.

Alternatively, the means for holding the stacked carrier elements are in the form of a shell comprising a substantially stiff material. The shell can be composed of two half-shells or a plurality of shell portions. The half-shells can be fitted onto the stacked carrier elements laterally or from above and below.

Alternatively, the holding means is in the form of a shell having a bottom and side walls so that the stacked carrier elements can be introduced into the shell through an opening in opposite relationship to the bottom.

### BRIEF DESCRIPTION OF THE SEVERAL VIEWS OF THE DRAWINGS

The invention is described hereinafter by means of preferred embodiments by way of example with reference to the accompanying drawings in which:

FIGS. 1a-c are cross-sectional views of a first embodiment of a packaging according to the invention,

FIG. 2 is a cross-sectional view of a second embodiment of a packaging according to the invention,

FIG. 3 is a side view of the packaging of FIG. 2,

FIG. 4 is an exploded view of a further embodiment of the packaging according to the invention,

FIG. 5 is an exploded sectional view of the packaging of FIG. 4,

FIG. 6 is a side view in partial cross-section of a further embodiment of the packaging according to the invention,

FIG. 7 is a cross-sectional view of the packaging of FIG. 6,

FIG. 8 is a side view of a further embodiment of a packaging according to the invention,

FIG. 9 is a cross-sectional view of the packaging of FIG. 8,

FIG. 10 is a further embodiment of a packaging according to the invention with a carrier element,

FIG. 11 is an exploded sectional view of the packaging of FIG. 10,

FIG. 12 is a further embodiment of a packaging according to the invention with a carrier element for a plurality of products, and

FIG. 13 is a cross-sectional view of the packaging of FIG. 12.

### DETAILED DESCRIPTION

The packagings shown in the Figures are intended for packaging slice-form, in particular thin brittle products such as wafers or solar cells or the like. In the description hereinafter, in respect of the products, reference is primarily made to wafers but that is to be interpreted as being by way of example and it is possible to package any other products, for example solar cells or the like. The products can be of a circular shape or can be square or rectangular or parallelepipedic. Other product shapes are also alternatively conceivable.

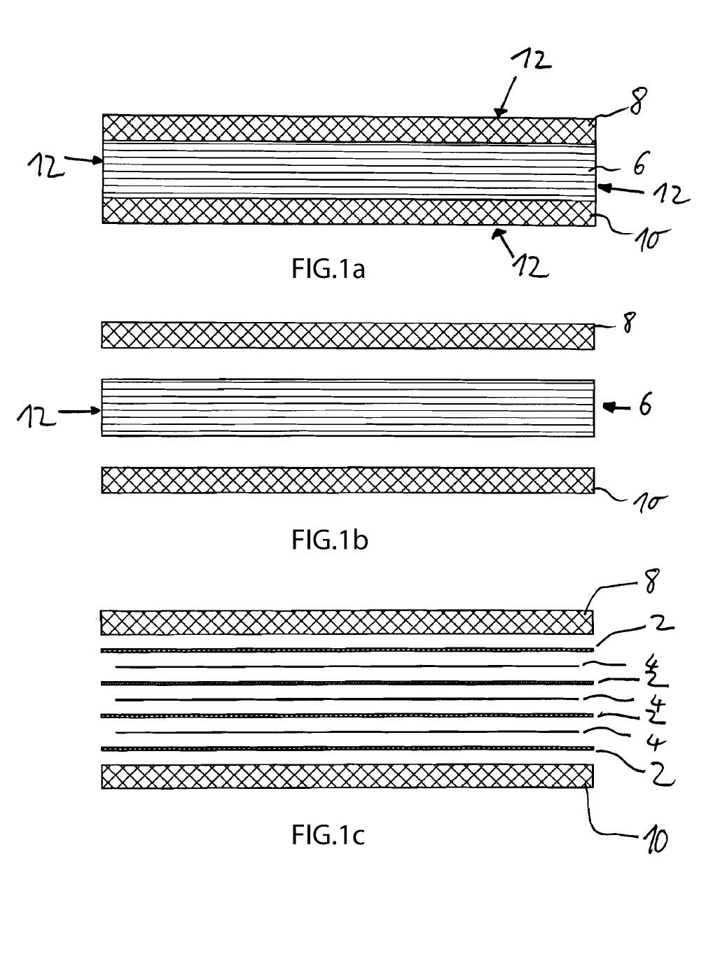

In the packaging shown in FIGS. 1a-c, a plurality of wafers or solar cells 2 are stacked in mutually superposed relationship. Separating elements 4 are arranged between the wafers 2 (see FIG. 1a). The wafers 2 together with the separating elements 4 form a stack or wafer stack 6 (FIG. 1b). Each separating element 4 represents a thin intermediate layer and is made from a deformable material such as for example cardboard, paper, tissue paper, film, felt, non-woven material, plastic, foam, biological degradable foam or laminated material. The separating element 4 is of substantially the same shape as a wafer 2 or is somewhat smaller than the wafer 2. In a manner not shown here, a separating element 4 can project laterally from the wafers 2 or the stack 6 so that it can be manually gripped. For that purpose, a projection in the manner of a tab or flap can be formed on the separating element 4 or however the separating element 4 can be of larger dimensions than the product 2.

An upper cover plate 8 and a lower cover plate 10 are fitted above and beneath the stack 6 respectively and protect the stack 6 and, thus, the individual products 2. They can be made from a foam material, cardboard, plastic material, felt, foam or other laminated material and can also be referred to as cushion element.

A film wraparound packaging which has a film 12 (see FIG. 1a) encloses the stack 6 and, in this embodiment, also the cover plates 8, 10. According to the invention, it is also possible for the stack 6 of individual products 2, optionally with the separating elements 4, to be wrapped in a film wraparound packaging 12. Optionally, a stack 6 wrapped in a film wraparound packaging together with the cover plates 8, 10 could be wrapped in a further outer film wraparound packaging 12 or alternatively in a shrinkable film (shrink film). The film 12 of the film wraparound packaging can be a transparent thin film of a plastic or paper which is coated or provided with an adhesive. In a manner not shown here, a perforation or a tear-open strip can be integrated in the film 12 in order to be able to easily open the film. A means for holding the stacked wafers 2 is afforded by the film 12.

In a manner not shown here, individual separating elements 4 are of such a configuration in respect of their structure that the product can be very easily released from the separating element 4, in particular by virtue of an air flow becoming easily possible between the separating element 4 and the product, such as for example by knobs, structured air passages, cut-outs or through openings in or on the separating element 4. For example knobs or depressions can be arranged at the top side and underside of the separating elements 4.

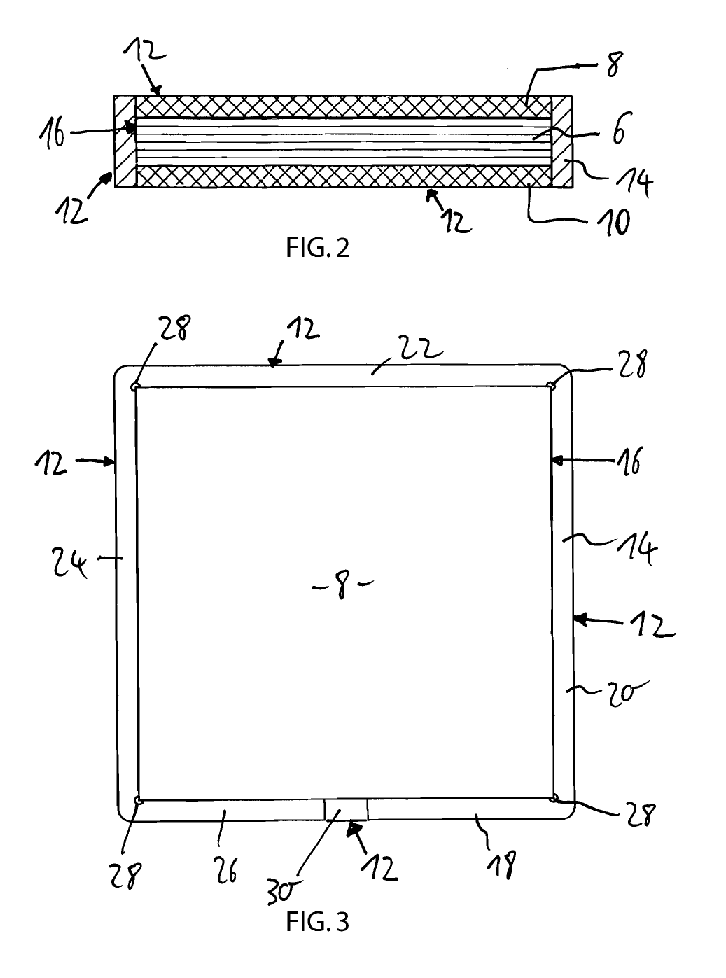

In the alternative embodiment shown in FIGS. 2 and 3, a stack 6 of wafers 2, optionally additionally with separating elements 4, is enclosed by cover plates 8, 10, as described with reference to FIG. 1. In addition, a cushion element 14 is arranged at the peripheral circumferentially extending edge 16 of the stack 6 of wafers 2 to provide additional protection from damage in particular to the edge region of the wafers 2. The height of the cushion element 14 corresponds to the height of the stack 6 plus the height or thickness of the cover plates 8 and 10, as FIG. 2 shows.

As can be seen from FIG. 3, the cushion element 14 extends substantially over the entire edge of the stack 6 and has a plurality of straight wall portions 18, 20, 22, 24, 26 which overall are adapted to the approximately rectangular outside contour of the stack 6. The packaging is fixed by means of a film 12 of a film wraparound packaging and holds the stack 6 and the cushion element 14 together under a stress. The cushion element 14 has recesses 28 which are so positioned that in the packaged condition they are arranged in opposite relationship to the corners of the wafers 2 so that there is no contact with the cushion element 14 at those delicate corners and thus the corners are protected from damage.

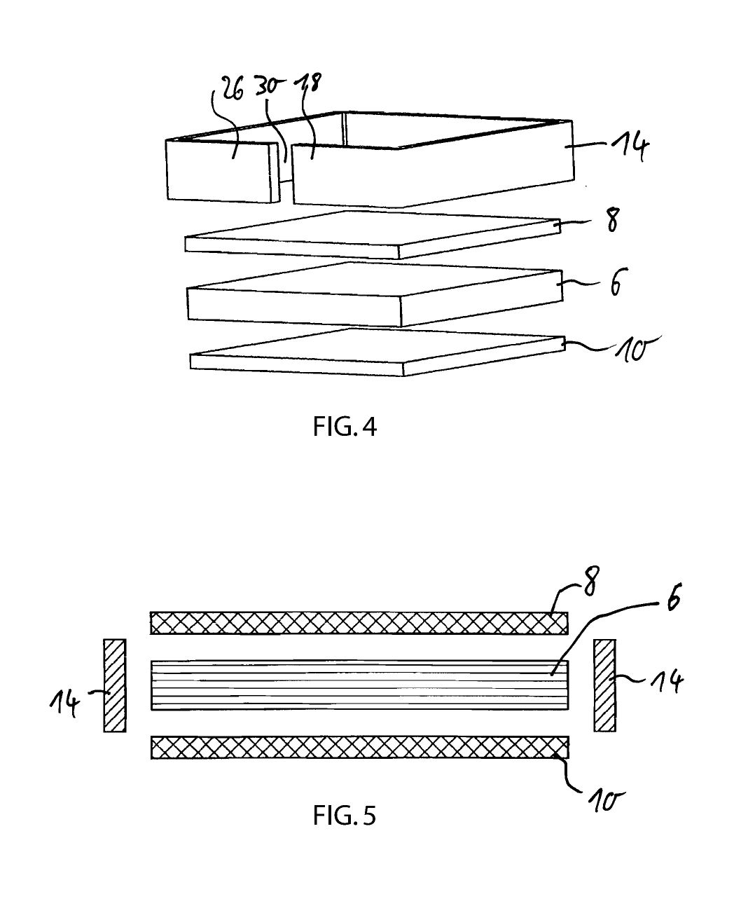

FIGS. 4 and 5 show the embodiment of FIGS. 2 and 3 in an exploded view, but without the film 12 of the film wraparound packaging. FIG. 4 shows that the overall length of the cushion element 14, in particular the two wall portions 18, 26, is or are so selected that in the packaged condition there is a gap 30 between the wall portions. In that way the cushion element 14 can always be fastened tautly around the stack 6 and fixed by means of the film 12 of the film wraparound packaging. The cushion element 14 and also the cover plates 8, 10 can be of increased strength at their outer surface, for example by being coated. That increases the strength in relation to mechanical loadings and stresses due to external actions.

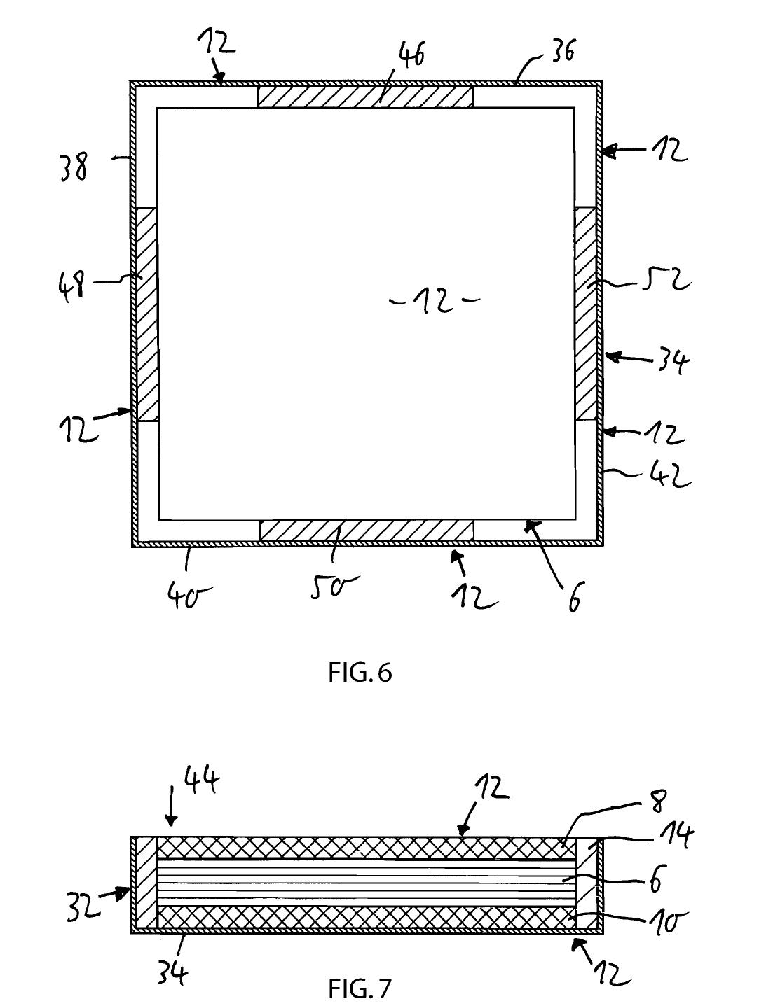

The packaging shown in FIGS. 6 and 7 partially differs from those described hereinbefore, in which respect the differences are described in greater detail hereinafter and reference is directed in regard to common aspects to the foregoing description; identical components are in this case denoted by the same references as above.

The stack 6 with wafers 2 is enclosed by an upper and lower cover plate 8, 10 and a cushion element 14. A shell 32 additionally forms a means for holding the stacked wafers or solar cells. The shell 32 has a bottom 34 and a plurality of side walls 36, 38, 40, 42 forming a peripherally extending edge (see FIG. 6). The stack 6 together with the cover plates 8, 10 and the cushion element 14 can be fitted into the shell 34 through an upper opening 44. In a manner not shown here, a stack 6 of wafers 2 which is wrapped in a film wraparound packaging comprising a film 12 could also be fitted directly into the shell 34. In the illustrated embodiment the upper cover plate 8 substantially closes the opening 44 of the shell 32. A shrinkable film 12 or alternatively a film 12 of a film wraparound packaging externally encloses the shell 32 so that the stack 6 of wafers 2 is securely packed in the packaging.

As FIG. 6 shows, the cushion element 14 comprises individual substantially straight cushion element portions 46, 48, 50, 52 (FIG. 6) which fix the stack 6 laterally within the shell 32 and protect same.

In a manner not shown here, the bottom 34 of the shell 32 has at least one groove into which can be introduced a tongue provided at the upper edge of the side walls 36, 38, 40, 42. A plurality of stacks 32 can be stacked in mutually superposed positioning relationship by means of the tongue and groove, by the tongues being inserted into the groove or grooves.

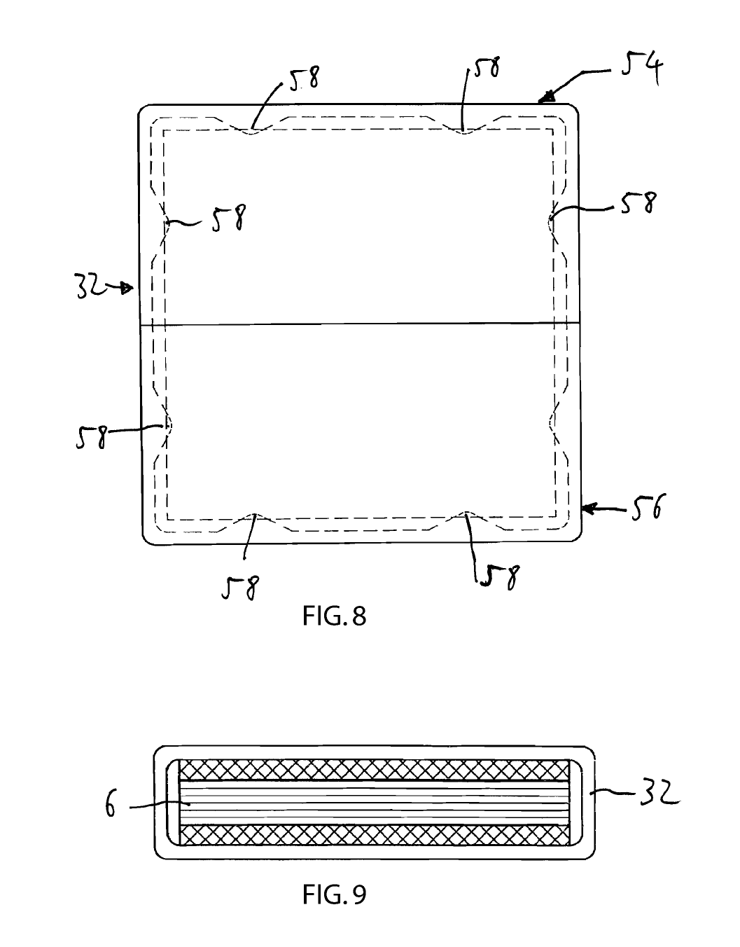

In the alternative embodiment shown in FIGS. 8 and 9, the shell 32 is formed from two half-shells 54, 56. The two half-shells 54, 56 can be pushed laterally onto the stack 6. Provided at the inner surface of the half-shells 54, 56 of the shell 32 are fixing elements in the form of a plurality of inwardly projecting projections 58 which come laterally into contact with the stack 6 at the edge thereof or alternatively with a cushion element 14 or portions 46, 48, 50, 52 which form a cushion element 14 to position the stacked wafers 6 within the shell 32.

In all the above-described embodiments, instead of a stack 6 of wafers which are optionally separated by separating elements 4, it would be possible to package a stack of wafers 2 or other products in slice form securely in the above-described manner, in which case however the products 2 are placed on carrier elements which are described in greater detail hereinafter. The carrier elements together with wafers 2 then form a stack 6 and are packaged in principle as described hereinbefore within the packaging.

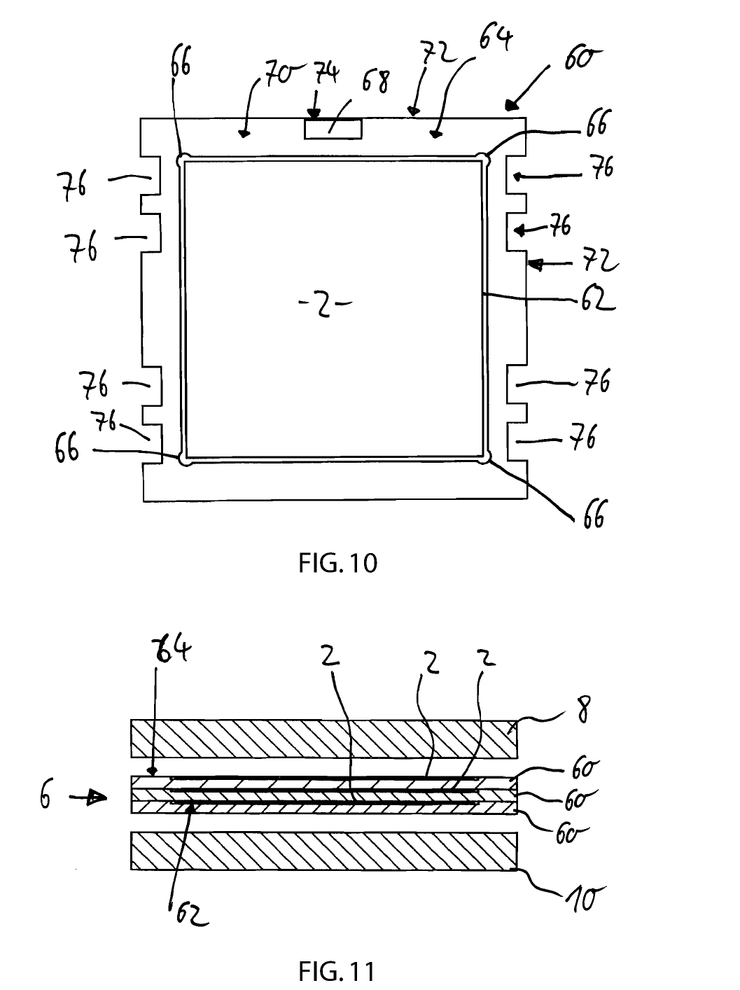

A carrier element 60 according to the invention is shown in the first embodiment in FIGS. 10 and 11. The FIG. 11 embodiment provides by way of example that three carrier elements are stacked one upon the other, with a product such as a wafer 2 being placed on each carrier element 60. An individual carrier element 60 already represents a packaging according to the invention. Wafers 2 and carrier elements 60 form a stack 6 which in accordance with the invention can be further packaged in the manner described hereinbefore with reference to FIGS. 1 through 8. An individual carrier element 60 according to the invention can also be packaged in another fashion (not shown here).

As is clearly apparent from FIG. 10, a wafer 2 (or another product) can be laid in a depression 62 which is formed at a top side of the carrier 60 and which is substantially adapted to the shape of the wafer. In the illustrated embodiment, the depression 62 is substantially parallelepipedic for receiving the wafer 2. Other shapes and in particular a circular depression 62 or a depression 62 in the shape of a portion of a cylinder can also be envisaged for receiving substantially circular products 2, or it is also possible to envisage other shapes. The depth of the depression 62 is preferably so selected that the product 2 is arranged completely within the depression 62 or the surface of the product 2 is substantially aligned with the surface 64 of the carrier element 60. At the same time, the depression 62 forms a means for positioning a wafer 2 on the carrier element 60. The depression 62 has a plurality of outwardly extending recesses 66 (see FIG. 10) which each have a somewhat rounded edge. Each corner of the wafer, by virtue of the recess 66, thus does not come into contact with the carrier element 60 and is thus particularly protected from (brittle) fracture.

As the Figures show, each carrier element 60 is so dimensioned that the thickness thereof is small in relation to width and/or length. In a manner not shown here, individual carrier elements are of such a configuration in respect of their surface structure that the product can be very easily released from the separating element, in particular by virtue of the fact that air flows are easily possible between the separating element and the product, such as for example by means of knobs, structured air passages, cut-outs or through openings in/on the separating element. Thus, a plurality of knobs and/or grooves can be provided on the carrier element 60 in the region of the depression 62, which form air passages which prevent a wafer 2 from “clinging” and thus enable easy removal of a wafer 2 from the carrier element 60. Air flows are possible in that way.

Disposed on the carrier element 60 is an information carrier 68, in the preferred embodiment on an upwardly facing side surface 70 in the region of the circumferentially extending edge 72 of the carrier element 60. The information carrier 68 can be a barcode, RFID, a data chip, a printed label or the like. The information carrier 68 is optionally placed in an optional depression 74.

As can also be seen from FIG. 10, a plurality of recess openings 76 are provided on the carrier element 60. In the illustrated embodiment, they are positioned at mutually opposite edges. By means of those recess openings 76 which in a manner not shown here can alternatively also be replaced by protruding projections, the carrier elements 60 if required can be positioned or guided within a container (not shown) or in production apparatuses, for example by a projection, for instance in the form of a bar or the like, being placed within a recess opening 76.

The carrier element 60 is made for example from paper, plastic material, film, deep-drawing film, metal or organically degradable, fixed-structure materials.

As described hereinbefore with reference to FIGS. 1 through 8, the stacks 6 of carrier elements 60 with wafers 2 can be protected by means of cushion elements, in particular cover plates 8, 10 or cushion elements 14, at the top side and/or underside and at the peripheral outside, and can be packaged in a film wraparound packaging by means of a film 12 and/or additionally placed in a shell as described hereinbefore and thus packaged. In that respect, reference is made in its full extent to the foregoing description.

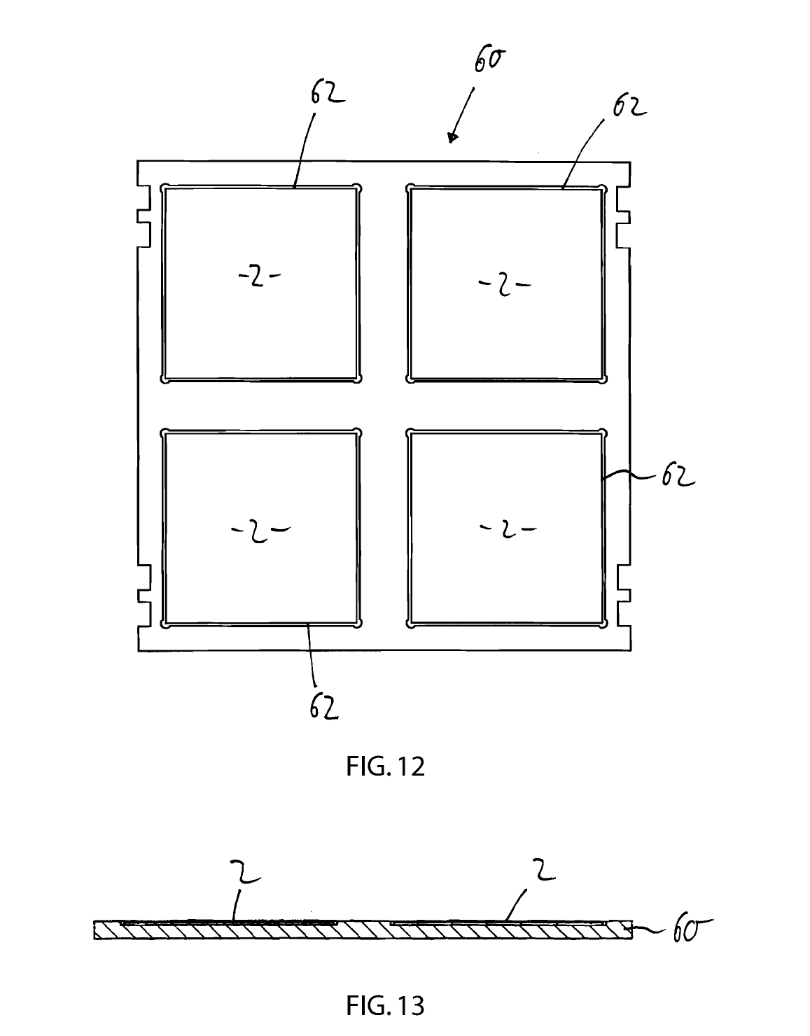

FIG. 12 shows an alternative embodiment of a carrier element 60 which has a series of aspects in common with the above-described embodiment. In regard to the common aspects, reference is directed to the foregoing description and the same references are employed. The differing features are described in greater detail hereinafter. The carrier element shown in FIG. 12 has a plurality of depressions 62, the Figure showing four thereof, for receiving a respective product 2, which are arranged in mutually juxtaposed relationship so that four wafers 2 can be accommodated. Alternatively, other arrangements of a plurality of depressions 62 are also conceivable, for example a plurality of circular depressions 62 arranged in a rectangular pattern or in one or more rows. As described hereinbefore a plurality of carrier elements 60 which can be stacked one upon the other with a plurality of wafers 2 form a stack 6 which can be packaged and wrapped with a shrinkable film or with a film wraparound packaging 12 and can be packaged in the above-described manner in a shell, optionally together with cushion element.

FIG. 13 shows the products 2 respectively arranged in a depression 62 in a sectional view. A plurality of, for example 5, 10 or also 15 or more carrier elements 60 can be present with therefore overall a multiplicity of products.

The invention is described in greater detail by means of the embodiments hereinafter:

Embodiment 1. Packaging for slice-form, in particular thin brittle products, characterized in that the packaging is a film wraparound packaging.

Embodiment 2. Packaging according to embodiment 1 characterized in that the products are wafers or solar cells.

Embodiment 3. Packaging according to embodiment 2 characterized in that the wafers or solar cells are stacked directly one upon the other and said wafer stack is wrapped directly in film.

Embodiment 4. Packaging according to one of the preceding embodiments characterized in that a cushioned and/or hard cover plate is disposed on the stack at top and bottom and the stack formed in that way is wrapped in film.

Embodiment 5. Packaging according to one of preceding embodiments 2 through 4 characterized in that one or more separating elements is placed between the wafers or solar cells of the stack and said wafer stack with separating element or elements is wrapped directly in film.

Embodiment 6. Packaging according to one of preceding embodiments 2 through 4 characterized in that a cushioned and/or hard cover plate is disposed on the stack at top and bottom and the stack formed in that way is wrapped in film.

Embodiment 7. Packaging according to one of the preceding embodiments characterized in that this can involve a combination of shrink film and film and film wraparound packaging.

Embodiment 8. Packaging according to one of the preceding embodiments characterized in that the film packaging provides a defined possibility of opening the film by way of a tear-strip or a perforation in the film.

Embodiment 9. Packaging in particular according to embodiments 1 through 8 characterized in that at least one separating element is arranged between adjacent wafers or solar cells.

Embodiment 10. Packaging according to embodiments 1 through 9 characterized in that a separating element is arranged between all adjacent wafers or solar cells.

Embodiment 11. Packaging according to embodiment 9 or embodiment 10 characterized in that the separating element is in the form of a thin intermediate layer comprising a deformable material, in particular cardboard, paper, tissue paper, film, felt, non-woven material, plastic, foam, biologically degradable foam or laminated material.

Embodiment 12. Packaging according to one of the preceding embodiments characterized in that the separating element is of substantially the same shape as a stacked wafer so that stacked adjacent wafers or solar cells are not in contact.

Embodiment 13. Packaging according to one of the preceding embodiments characterized in that the separating element is of such a size and/or shape that adjacent wafers or solar cells are only partially not in direct contact with each other.

Embodiment 14. Packaging according to one of the preceding embodiments characterized in that the separating element is of such a size and/or is so arranged between adjacent wafers or solar cells that the separating element partially projects laterally from adjacent wafers or solar cells.

Embodiment 15. Packaging according to one of the preceding embodiments characterized in that a plurality of separating elements are of substantially identical or differing nature, in particular that the separating elements are laminated from different materials to build up over the laminating structure a pressure against the packaging film in the overall pack.

Embodiment 16. Packaging according to one of the preceding embodiments characterized in that individual separating elements are of such a configuration in respect of their surface structure that the product can be very easily released from the separating element, in particular by virtue of the fact that air flow becomes easily possible between the separating element and the product, such as for example by means of knobs, structured air passages, cut-outs or through openings in/on the separating element.

Embodiment 17. Packaging for slice-form products, comprising

a means for holding a plurality of stacked wafers or solar cells, in particular according to one of the preceding claims,

characterized in that at least one cushion element is arranged at an outside of the stacked wafers or solar cells.

Embodiment 18. Packaging according to embodiment 17 characterized in that a respective cushion element is arranged at mutually opposite sides of the stacked wafers or solar cells.

Embodiment 19. Packaging according to embodiment 17 or embodiment 18 characterized in that the cushion element is substantially of the same size as a wafer or a solar cell.

Embodiment 20. Packaging according to one of the preceding embodiments characterized in that a cushion element or a plurality of cushion elements is or are arranged at the peripheral edge of the stacked wafers or solar cells.

Embodiment 21. Packaging according to embodiment 20 characterized in that there is provided a cushion element which extends substantially over the entire edge and which preferably has a plurality of straight wall portions.

Embodiment 22. Packaging according to embodiment 21 characterized in that the cushion element has a plurality of and preferably 4 recesses which in the packaged condition are arranged substantially opposite the corners of the wafers or solar cells.

Embodiment 23. Packaging according to at least one of embodiments 17 through 22 characterized in that at its outside the cushion element is of a higher strength or has a reinforcing layer.

Embodiment 24. Packaging according to one of embodiments 17 through 23 characterized in that the cushion element is formed from a foam material, cardboard, plastic, felt, biologically degradable foam or laminated material.

Embodiment 25. Packaging according to at least one of the preceding embodiments characterized in that the means for holding the stacked wafers or solar cells are in the form of a shrinkable film.

Embodiment 26. Packaging according to embodiment 25 characterized in that the shrinkable film at least partially encloses and holds together the stacked wafers or solar cells and the cushion element or elements.

Embodiment 27. Packaging according to at least one of the preceding embodiments characterized in that the means for holding the stacked wafers or solar cells are in the form of a shell comprising a substantially stiff material.

Embodiment 28. Packaging according to embodiment 27 characterized in that the shell is composed of two half-shells or a plurality of shell portions.

Embodiment 29. Packaging according to embodiment 28 characterized in that the half-shells can be fitted laterally onto the stacked wafers or solar cells.

Embodiment 30. Packaging according to embodiment 29 characterized in that the half-shells can be fitted from above and below onto the stacked wafers or solar cells.

Embodiment 31. Packaging according to one of the preceding embodiments characterized in that the holding means are in the form of a shell comprising a bottom and side walls and the stacked wafers or solar cells can be fitted into an opening in opposite relationship to the bottom and into the container.

Embodiment 32. Packaging according to embodiment 31 characterized in that cushion elements are arranged between the bottom and the side walls and the stacked wafers or solar cells.

Embodiment 33. Packaging according to embodiment 32 characterized in that a cover in the form of a cushion element closes the shell.

Embodiment 34. Packaging according to embodiment 33 characterized in that a shrinkable film at least partially encloses the shell.

Embodiment 35. Packaging according to embodiment 34 characterized in that the bottom and the cover are provided with a groove and tongue so that the containers are stackable.

Embodiment 36. Packaging according to embodiment 35 characterized in that fixing elements formed on the shell provide that the stacked wafers or solar cells are fixed.

Embodiment 37. Packaging for slice-form products, in particular according to one of the preceding embodiments characterized by a carrier element for carrying a wafer or a solar cell, which is so adapted that it is stackable together with a plurality of carrier elements.

Embodiment 38. Packaging according to embodiment 37 characterized in that the carrier element is so dimensioned that a wafer or a solar cell can be placed completely on one side of the carrier element.

Embodiment 39. Packaging according to embodiment 37 or embodiment 38 characterized in that the carrier element has means for positioning a wafer or a solar cell on the carrier element.

Embodiment 40. Packaging according to one of preceding embodiments 37 through 39 characterized in that the carrier element has a depression in which a wafer or a solar cell can be laid.

Embodiment 41. Packaging according to embodiment 40 characterized in that the depression is so shaped that it substantially corresponds to the contour of a wafer or a solar cell and the wafer or the solar cell is arranged completely or substantially within the depression.

Embodiment 42. Packaging according to embodiment 41 characterized in that the depression is substantially parallelepipedic, square or cylindrical.

Embodiment 43. Packaging according to one of embodiments 40 through 42 characterized in that an outwardly extending recess is provided in one or all corners of a depression.

Embodiment 44. Packaging according to embodiment 43 characterized in that the recess has substantially a rounded edge.

Embodiment 45. Packaging according to one of the preceding embodiments characterized in that there are provided a plurality of means for positioning a wafer or a solar cell and/or a plurality of depressions on the carrier element.

Embodiment 46. Packaging according to embodiment 45 characterized in that two, three or more positioning means or depressions are provided on the carrier element, preferably in such a way that two, three or more wafers or solar cells can be placed more or less uniformly spaced in relation to each other on the carrier element.

Embodiment 47. Packaging according to one of the preceding embodiments characterized in that individual carrier elements are of such a configuration in respect of their surface structure that the product can be very easily released from the separating element, in particular by virtue of the fact that air flows are easily possible between the separating element and the product, such as for example by virtue of knobs, structured air passages, cut-outs or through openings in/on the separating element.

Embodiment 48. Packaging according to embodiment 47 characterized in that provided on a side of the carrier element on which a wafer or a solar cell can be placed are a plurality of raised portions on which a wafer or a solar cell can be laid.

Embodiment 49. Packaging according to one of preceding embodiments 47 characterized in that a plurality of depressions are provided on a side of the carrier element on which a wafer or a solar cell can be placed.

Embodiment 50. Packaging according to at least one of preceding embodiments 37 through 49 characterized in that the carrier element is so dimensioned that its thickness is small in relation to the width and/or length.

Embodiment 51. Packaging according to one of embodiments 37 through 50 characterized in that the carrier element is adapted to receive a wafer or a solar cell or a plurality of mutually juxtaposed wafers or solar cells and a plurality of carrier elements are stackable one upon the other in such a way that the stacked wafers or solar cells do not touch each other.

Embodiment 52. Packaging according to one of preceding embodiments 37 through 51 characterized in that an information carrier is arranged on the carrier element.

Embodiment 53. Packaging according to embodiment 52 characterized in that the information carrier is arranged in the region of the edge of the carrier element, preferably on a side surface in adjacent relationship with the edge of the carrier element.

Embodiment 54. Packaging according to one of embodiments 52 and 53 characterized in that the information carrier has a barcode, RFID, data chip, printed label or the like.

Embodiment 55. Packaging according to one of embodiments 37 through 54 characterized in that one or more recess openings and/or one or more projections is or are provided in the edge region of the carrier element.

Embodiment 56. Packaging according to embodiment 55 characterized in that the recess openings or projections are provided at mutually opposite edges of the carrier element.

Embodiment 57. Packaging according to embodiment 55 characterized in that a recess opening is of a substantially rectangular shape or rounded.

Embodiment 58. Packaging according to one of embodiments 37 through 57 characterized in that the carrier element is made from cardboard, plastic material, film, deep-drawing film, metal or organically degradable fixed-structure materials.

Embodiment 59. Packaging according to one of embodiments 37 through 58 characterized in that at least one cushion element is arranged at an outside of stacked carrier elements.

Embodiment 60. Packaging according to embodiment 59 characterized in that a cushion element is arranged at an outside or both oppositely disposed outsides of the stacked carrier elements.

Embodiment 61. Packaging according to embodiment 60 characterized in that a cushion element is of substantially the same size as a carrier element.

Embodiment 62. Packaging according to one of preceding embodiments 59 characterized in that a cushion element or a plurality of cushion elements is or are arranged at the peripheral edge of the stacked carrier elements.

Embodiment 63. Packaging according to embodiment 62 characterized in that there is provided a cushion element extending substantially over the entire edge.

Embodiment 64. Packaging according to embodiments 59 through 63 characterized in that at its outside the cushion element is of greater strength or has a reinforcing layer.

Embodiment 65. Packaging according to one of embodiments 59 through 64 characterized in that the cushion element is made from a foam, cardboard, plastic material or laminated materials.

Embodiment 66. Packaging according to at least one of preceding embodiments 37 through 65 characterized by means for holding the stacked carrier elements.

Embodiment 67. Packaging according to embodiment 66 characterized in that the means are in the form of a shrinkable film which at least partially encloses the stacked carrier elements and optionally the cushion element or elements.

Embodiment 68. Packaging according to embodiment 66 characterized in that the means for holding the stacked carrier elements are in the form of a shell comprising a substantially stiff material.

Embodiment 69. Packaging according to embodiment 68 characterized in that the shell is composed of two half-shells or a plurality of shell portions.

Embodiment 70. Packaging according to embodiment 69 characterized in that the half-shells can be fitted laterally onto the stacked carrier elements.

Embodiment 71. Packaging according to embodiment 70 characterized in that the half-shells can be fitted from above and below onto the stacked carrier elements.

Embodiment 72. Packaging according to one of the preceding embodiments characterized in that the holding means are in the form of a shell comprising a bottom and side walls and the stacked carrier elements can be fitted into an opening in opposite relationship to the bottom and into the shell.

What is claimed is:

1-15. (canceled)

16. A packaging for at least one product, the packaging comprising:
a film configured to wrap around the at least one product.

17. The packaging of claim 16 wherein the at least one product is a plurality of wafers.

18. The packaging of claim 17 wherein the wafers are stacked directly upon each other to define a stack, and the stack is wrapped directly in the film.

19. The packaging of claim 18 further comprising:
a first cover plate disposed at the top of the stack; and
a second cover plated disposed at the bottom of the stack,
wherein the stack, the first cover plate, and the second cover plate are wrapped in the film.

20. The packaging of claim 18 further comprising:
one or more separating elements placed between the wafers of the stack, and the stack and the one or more separating elements are wrapped directly in the film.

21. The packaging of claim 16 further comprising:
an outer shrink film combined with the film.

22. The packaging of claim 18 further comprising:
a separating element arranged between an adjacent pair of the wafers in the stack, the separating element in the form of a thin intermediate layer comprising a deformable material.

23. The packaging of claim 22 wherein the deformable material is cardboard, paper, tissue paper, film, felt, non-woven material, plastic, foam, biologically degradable foam, or laminated material.

24. The packaging of claim 22 wherein the separating element has a size and/or an arrangement between the adjacent pair of the wafers that the separating element partially projects laterally from adjacent pair of the wafers.

25. The packaging of claim 18 further comprising:
a plurality of separating elements arranged between adjacent pairs the wafers in the stack, each of the separating elements in the form of a thin intermediate layer comprising a deformable material.

26. The packaging of claim 25 wherein the separating elements are composed of laminations of different materials configures to apply a pressure against the film.

27. The packaging of claim 25 wherein the separating elements are configured with a surface structure that the wafers can be released from the separating element.

28. The packaging of claim 27 wherein the surface structure is configured to promote air flow that releases the wafers from the separating elements.

29. The packaging of claim 25 wherein the surface structure is knobs, structured air passages, cut-outs, through openings in each separating element, or through openings on each separating element.

30. The packaging of claim 18 further comprising:
a first cushion element arranged at an outside edge of the stack.

31. The packaging of claim 30 further comprising:
a second cushion element arranged at a mutually opposite side of the stack from the first cushion element.

32. The packaging of claim 30 wherein the first cushion element is arranged at an outside edge of the stack.

33. The packaging of claim 30 wherein the first cushion element extends substantially over the entire outside edge.

34. The packaging of claim 33 wherein the first cushion element has a plurality of straight wall portions.

35. The packaging of claim 30 wherein the first cushion element has a plurality of recesses which, in the packaged condition, are arranged substantially opposite the corners of the wafers in the stack.

36. The packaging of claim 30 wherein the first cushion element has a higher strength at a perimeter than at a location inside the perimeter.

37. The packaging of claim 30 wherein the first cushion element has a reinforcing layer disposed at a perimeter of the first cushion element.

38. The packaging of claim 18 further comprising:
a shell including a plurality of shell portions configured to be fitted about the stack of the wafers or the solar cells.

39. The packaging of claim 18 further comprising:
a shell including a bottom wall and a plurality of side walls, and the stack of the wafers or the solar cells can be fitted into an opening in opposite relationship to the bottom wall and into the shell.

40. The packaging of claim 39 wherein a plurality of cushion elements are arranged between the bottom wall, the side walls, and the stack of the wafers.

41. The packaging of claim 39 further comprising:
a cushion element defining a cover that closes the shell.

42. The packaging of claim 39 further comprising:
a shrinkable film or a cardboard box at least partially enclosing the shell.

43. The packaging of claim 16 further comprising:
a carrier element configured to carry the at least one product and dimensioned such that the at least one product can be placed completely on a side of the carrier element, the carrier element further configured to be stackable together with a plurality of additional carrier elements.

44. The packaging of claim 43 further comprising:
means for positioning the at least one product on the carrier element.

45. The packaging of claim 43 wherein the carrier element includes a depression in which the at least one product is laid.

46. The packaging of claim 45 wherein the depression is shaped to substantially correspond to a contour of the at least one product, and the at least one product is arranged completely or substantially within the depression.

47. The packaging of claim 46 wherein the depression is substantially parallelepipedic, substantially square, or substantially cylindrical.

48. The packaging of claim 43 further comprising:
an information carrier arranged on the carrier element.

49. The packaging of claim 48 wherein the information carrier comprises a barcode, a RFID, a data chip, or a printed label.
